(19) United States
(12) Patent Application Publication
(10) Pub. No.: US 2026/0277098 A1
(43) Pub. Date: Sep. 17, 2026

(54) SEMICONDUCTOR PHOTORESIST COMPOSITION AND METHOD OF FORMING PATTERNS USING THE COMPOSITION

(71) Applicant: Samsung SDI Co., Ltd., Yongin-si (KR)

(72) Inventors: Miyeon HAN, Suwon-si (KR); Jihyun YOON, Suwon-si (KR)

(21) Appl. No.: 19/438,903

(22) Filed: Jan. 2, 2026

(30) Foreign Application Priority Data
Mar. 14, 2025 (KR) 10-2025-0033526

(51) Int. Cl. G03F 7/004; G03F 7/00; G03F 7/20; H10P 50/00

(52) U.S. Cl. CPC G03F 7/0042; G03F 7/0045; G03F 7/2004; G03F 7/70033; H10P 50/71; H10P 50/73

(57) ABSTRACT

A semiconductor photoresist composition includes an organometallic compound; a compound containing at least one nitro group; an organic acid compound or an alcohol compound; and a solvent. A method of forming patterns includes: forming an etching-objective layer on a substrate; applying the semiconductor photoresist composition to the etching-objective layer to form a photoresist film; patterning the photoresist film to form a photoresist pattern; and etching the etching-objective layer using the photoresist pattern as an etching mask.

### CROSS-REFERENCE TO RELATED APPLICATION

The present application claims priority to and the benefit of Korean Patent Application No. 10-2025-0033526, filed on Mar. 14, 2025, with the Korean Intellectual Property Office, the entire content of which is hereby incorporated by reference.

### BACKGROUND

### 1. Field

Embodiments of his disclosure relate to a semiconductor photoresist composition and a method of forming patterns using the same.

### 2. Description of the Related Art

EUV (extreme ultraviolet) lithography is paid attention to as one technology for manufacturing a next generation semiconductor device. The EUV lithography is a pattern-forming technology using an EUV ray having a wavelength of 13.5 nm as an exposure light source. According to the EUV lithography, an extremely fine pattern (e.g., less than or equal to 20 nm) may be formed in an exposure process during a manufacture of a semiconductor device.

Extreme ultraviolet (EUV) lithography is realized through development of compatible photoresists which can be performed at a spatial resolution of less than or equal to 16 nm. Currently, efforts to satisfy insufficient specifications of existing chemically amplified (CA) photoresists such as a resolution, a photospeed, and feature roughness (or also referred to as a line edge roughness or LER) for the next generation device are being made.

An intrinsic image blurring due to an acid catalyzed reaction in these polymer-type photoresists limits a resolution in small feature sizes, which has been present in electron beam (e-beam) lithography for a long time. The chemically amplified (CA) photoresists are designed for high sensitivity, but because their general elemental makeups reduce light absorbance of the photoresists at a wavelength of 13.5 nm and thus decrease their sensitivity, the chemically amplified (CA) photoresists may at least partially have more difficulties under an EUV exposure.

The CA photoresists may have difficulties in the small feature sizes due to roughness issues, and line edge roughness (LER) of the CA photoresists experimentally turns out to be increased, as a photospeed is decreased partially due to an essence of acid catalyst processes. Accordingly, a high-performance photoresist is required or desired in a semiconductor industry because of these defects and problems of the CA photoresists.

In order to overcome the aforementioned drawbacks of the chemically amplified (CA) organic photosensitive composition, an inorganic photosensitive composition has been researched. The inorganic photosensitive composition is mainly used for negative tone patterning having resistance against removal by a developer composition due to chemical modification through nonchemical amplification mechanism. The inorganic composition contains an inorganic element having a higher EUV absorption rate than hydrocarbon and thus may secure sensitivity through the nonchemical amplification mechanism and is less sensitive with respect to a stochastic effect and thus has low line edge roughness and a small number of defects.

Inorganic photoresists based on peroxopolyacids of tungsten mixed with tungsten, niobium, titanium, and/or tantalum have been reported as radiation sensitive materials for patterning.

These materials are effective for patterning large pitches for bilayer configuration as far ultraviolet (deep UV), X-ray, and electron beam sources. More recently, if (e.g., when) cationic hafnium metal oxide sulfate (HfSOx) materials along with a peroxo complexing agent has been used to image a 15 nm half-pitch (HP) through projection EUV exposure, impressive performance has been obtained. This system exhibits the highest performance of a non-CA photoresist and has a practicable photospeed near to a requirement or a level suitable for an EUV photoresist. However, the hafnium metal oxide sulfate material having the peroxo complexing agent has a few practical drawbacks. First, these materials are coated in a mixture of corrosive sulfuric acid/hydrogen peroxide and have insufficient shelf-life stability. Second, a structural change thereof for performance improvement as a composite mixture is not easy. Third, development should be performed in a TMAH (tetramethylammonium hydroxide) solution at an extremely high concentration of 25 wt % and/or the like.

Recently, active research has been conducted as molecules including tin have excellent absorption of extreme ultraviolet rays. As for an organotin polymer among them, alkyl ligands are dissociated by light absorption and/or secondary electrons produced thereby, and are crosslinked with adjacent chains through oxo bonds and thus enable the negative tone patterning which may not be removed by an organic developer. This organotin polymer exhibits greatly improved sensitivity as well as maintains a resolution and line edge roughness, but the patterning characteristics should be additionally improved for commercial availability.

### SUMMARY

Some example embodiments provide a semiconductor photoresist composition capable of improving the profile of a pattern.

Some example embodiments provide a method of forming patterns using the semiconductor photoresist composition.

A semiconductor photoresist composition according to some example embodiments includes an organometallic compound; a compound containing at least one nitro group; an organic acid compound or an alcohol compound; and a solvent.

A method of forming patterns according to some example embodiments includes forming an etching-objective layer on a substrate; applying the semiconductor photoresist composition to the etching-objective layer to form a photoresist film; patterning the photoresist film to form a photoresist pattern; and etching the etching-objective layer using the photoresist pattern as an etching mask.

The semiconductor photoresist composition according to some example embodiments may reduce an influence of variables during pattern formation and improve the profile of the pattern, and a pattern formed using the semiconductor photoresist composition can implement excellent resolution.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1A-1E are cross-sectional views illustrating a method of forming patterns using a semiconductor photoresist composition according to some example embodiments.

### DETAILED DESCRIPTION

Hereinafter, referring to the drawings, embodiments are described in detail. In the following description of the present disclosure, the well-known functions or constructions will not be described in order to clarify the subject matter of the present disclosure.

In order to clearly illustrate the subject matter of the present disclosure, certain description and relationships may be omitted, and throughout the disclosure, the same or similar configuration elements are designated by the same reference numerals. Also, because the size and thickness of each configuration shown in the drawing may be arbitrarily shown for better understanding and ease of description, the present disclosure is not necessarily limited thereto.

In the drawings, the thickness of layers, films, panels, regions, and/or the like, may be enlarged for clarity. In the drawings, the thickness of a part of layers or regions, and/or the like, may be exaggerated for convenience of explanation. It will be understood that if (e.g., when) an element such as a layer, film, region, or substrate is referred to as being “on” another element, it can be directly on the other element or intervening elements may also be present.

The terminology used herein is used to describe embodiments only, and is not intended to limit the present disclosure. The singular expression includes the plural expression unless the context clearly dictates otherwise.

As used herein, “combination thereof” means a mixture, a laminate, a composite, a copolymer, an alloy, a blend, a reaction product, and/or the like of the constituents.

In embodiments, “or” is not to be construed as an exclusive meaning, for example, “A or B” is construed to include A, B, A+B, and the like.

In embodiments, it should be understood that terms such as “comprises,” “includes,” or “have” are intended to designate the presence of an embodied feature, number, step, element, or a combination thereof, but it does not preclude the possibility of the presence or addition of one or more other features, number, step, element, or a combination thereof.

As used herein, “substituted” refers to replacement of a hydrogen atom by deuterium, a halogen, a hydroxyl group, a carboxyl group, a thiol group, a cyano group, a nitro group, —NRR′ (wherein, R and R′ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen atom by another substituent and remaining of the hydrogen atom.

As used herein, if (e.g., when) a definition is not otherwise provided, “alkyl group” refers to a linear or branched aliphatic hydrocarbon group. The alkyl group may be “saturated alkyl group” without any double bond or triple bond (e.g., without any carbon-carbon double bond or carbon-carbon triple bond).

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, “heteroalkyl group” refers to an alkyl group containing at least one heteroatom selected from N, O, S, Se, Te, Si, and P.

As used herein, if (e.g., when) a definition is not otherwise provided, “cycloalkyl group” refers to a monovalent cyclic aliphatic hydrocarbon group.

The cycloalkyl group may be a C3 to C8 cycloalkyl group, for example, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but is not limited thereto.

As used herein, “heterocycloalkyl group” refers to a cycloalkyl group containing at least one heteroatom selected from N, O, S, Se, Te, Si, and P.

As used herein, “aryl group” refers to a substituent in which all atoms in the cyclic substituent have a p-orbital and these p-orbitals are conjugated and may include a monocyclic or fused ring polycyclic functional group (e.g., rings sharing adjacent pairs of carbon atoms).

As used herein, “heteroaryl group” may refer to an aryl group including at least one heteroatom selected from N, O, S, P, and Si. Two or more heteroaryl groups are linked by a sigma bond directly, or if (e.g., when) the heteroaryl group includes two or more rings, the two or more rings may be fused. If (e.g., when) the heteroaryl group is a fused ring, each ring may include one to three heteroatoms.

As used herein, “arylalkyl group” means a substituent in which one or more hydrogens of an alkyl group are replaced by an aryl group.

As used herein, “heteroarylalkyl group” refers to an arylalkyl group containing at least one heteroatom selected from N, O, S, Se, Te, Si, and P.

As used herein, “alkylcarbonyl group” refers to a substituent in which one or more hydrogen atoms of a carbonyl group are replaced by an alkyl group.

As used herein, “alkenyl group” refers to an aliphatic unsaturated alkenyl group including at least one double bond (e.g., at least one carbon-carbon double bond) as a linear or branched aliphatic hydrocarbon group.

As used herein, “alkynyl group” refers to an aliphatic unsaturated alkynyl group including at least one triple bond (e.g., at least one carbon-carbon triple bond) as a linear or branched aliphatic hydrocarbon group.

Hereinafter, a semiconductor photoresist composition according to some example embodiments is described.

A semiconductor photoresist composition according to some example embodiments includes an organometallic compound; a compound containing at least one nitro group; an organic acid compound or an alcohol compound; and a solvent.

In general, a method of forming patterns by using a semiconductor photoresist composition including an organometallic compound includes coating the photoresist composition on an etching-objective layer, so that the organometallic compound, its cluster molecules (e.g., clusters of the organometallic compound), or a combination thereof in the photoresist composition may be coated on the etching-objective layer, and then, proceeding with a first baking process, an exposure process, a second baking process, and a development process to remove an organic material in the photoresist composition and thus to pattern a metal oxide.

In embodiments, the patterning of the metal oxide is affected by various suitable variables such as a temperature, a solvent, a concentration, a catalyst, an atmosphere, and/or the like, and the smaller pattern size, the relatively larger the effect. In general, because a pattern formed by a photoresist composition including an organometallic compound has a very small size in a range from several nm to several tens of nanometers, pattern formation may be more affected by the process conditions than a comparative photoresist.

For example, if (e.g., when) forming a pattern using a photoresist composition, the sensitivity is affected by the concentration of nitrogen oxides (NOx) in the atmosphere in which the pattern is formed. NOx is a highly reactive substance that exists in the atmosphere and may react with moisture, sunlight, and/or the like in the atmosphere to cause phenomena such as smog and/or the like, wherein if (e.g., when) the concentration of NOx exceeds a set or predetermined level, there is a problem that a pattern width and/or the like, which are checked after the development, differ from target values.

A semiconductor photoresist composition according to some example embodiments comprises a compound including at least one nitro group, which is capable of removing radicals of nitrogen oxides and/or reducing the reactivity of a central metal in an organometallic compound toward radicals and/or nitrogen oxides. Accordingly, the semiconductor photoresist composition according to some example embodiments may maintain excellent photoresist performance even in an environment where the concentration of nitrogen oxide in the atmosphere changes as the influence on nitrogen oxide is reduced, and may improve the pattern profile such as increasing the uniformity of the pattern.

The compound containing at least one nitro group may be at least one compound selected from a saturated or unsaturated aliphatic compound containing at least one nitro group, and an aromatic ring compound containing at least one nitro group.

The compound containing at least one nitro group may be a compound represented by Chemical Formula 1:

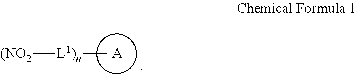

In Chemical Formula 1, L¹ is a single bond (e.g., a single covalent bond) or a substituted or unsubstituted C1 to C10 alkylene group (wherein, —CH₂— in the alkylene may be replaced with —O—), A is at least one selected from a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, and a substituted or unsubstituted C1 to C30 alkylcarbonyl group, and n is an integer greater than or equal to 1 and less than or equal to the bonding valence of A.

In Chemical Formula 1, L¹ may be a single bond (e.g., a single covalent bond) or a substituted or unsubstituted C1 to C8 alkylene group, for example, a single bond (e.g., a single covalent bond) or a substituted or unsubstituted C1 to C7 alkylene group, or a single bond (e.g., a single covalent bond) or a substituted or unsubstituted C1 to C5 alkylene group. In L¹ of Chemical Formula 1, one or at least one —CH₂— in alkylene (e.g., in the substituted or unsubstituted C1 to C8 alkylene group) may be replaced with —O—.

In Chemical Formula 1, A may be at least one selected from a substituted or unsubstituted C1 to C20 alkyl group, a substituted or unsubstituted C2 to C30 heteroalkyl group, a substituted or unsubstituted C6 to C30 aryl group, and a substituted or unsubstituted C7 to C30 arylalkyl group. In embodiments, for example, in Chemical Formula 1, A may be at least one selected from a substituted or unsubstituted C1 to C15 alkyl group, a substituted or unsubstituted C6 to C25 aryl group, and a substituted or unsubstituted C7 to C25 arylalkyl group, and may be at least one selected from the group consisting of a substituted or unsubstituted C1 to C8 alkyl group, a substituted or unsubstituted C6 to C20 aryl group, and a substituted or unsubstituted C7 to C20 arylalkyl group.

In Chemical Formula 1, n may be an integer from 1 to 8, for example, an integer from 1 to 5, 1 to 4, or 1 to 3.

As an example, in Chemical Formula 1, L¹ may be a single bond (e.g., a single covalent bond) or a substituted or unsubstituted C1 to C5 alkylene group (wherein one or at least one —CH₂— in the alkylene group may be replaced with —O—), A may be at least one selected from a substituted or unsubstituted C1 to C8 alkyl group, a substituted or unsubstituted C6 to C20 aryl group, and a substituted or unsubstituted C7 to C20 arylalkyl group, and n may be an integer of 1 to 3.

The compound containing at least one nitro group may be selected from compounds represented by Chemical Formula 1-1 to Chemical Formula 1-12:

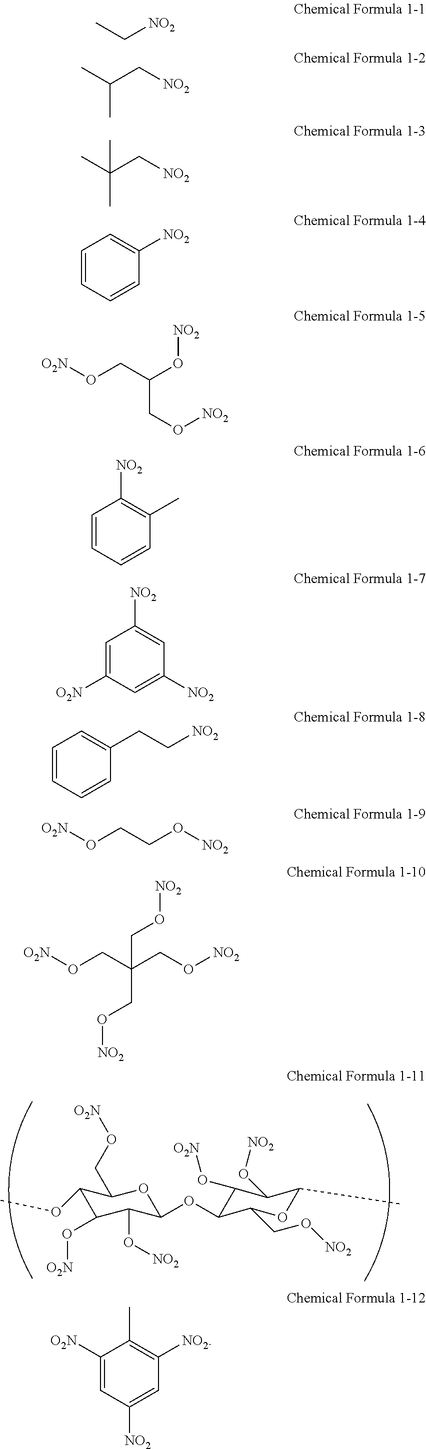

The compound containing at least one nitro group may be included in the semiconductor photoresist composition an amount of about 0.01 wt % to about 10 wt %, for example, about 0.01 wt % to about 8 wt %, about 0.01 wt % to about 5 wt %, about 0.01 wt % to about 3 wt %, about 0.01 wt % to about 1 wt %, or about 0.05 wt % to about 1 wt % based on 100 wt % of the semiconductor photoresist composition. If (e.g., when) the amount of the compound containing at least one nitro group satisfies the above ranges, the pattern-forming capability can be improved while the influence of nitrogen oxides is reduced.

The semiconductor photoresist composition includes an organic acid compound, and the organic acid compound may be a compound containing at least one carboxyl group. For example, the compound containing at least one carboxyl group may be at least one compound selected from a saturated or unsaturated aliphatic compound containing at least one carboxyl group, and an aromatic ring compound containing at least one carboxyl group.

For example, the compound containing at least one carboxyl group may include at least one selected from benzoic acid, glycolic acid, malonic acid, succinic acid, 1,2,3,4-butanetetracarboxylic acid, citric acid, tartaric acid, tricarballylic acid, lactic acid, thioglycolic acid, dithiodiglycolic acid, thiodiglycolic acid, phthalic acid, maleic acid, L-aspartic acid, p-toluenesulfonic acid, methanesulfonic acid, and benzenesulfonic acid, and for example may include benzoic acid.

The alcohol compound may include at least one selected from a monohydric alcohol and a polyhydric alcohol, and may be for example a monohydric alcohol. If (e.g., when) the alcohol compound includes a monovalent compound, the pattern-forming capability may be improved while the influence of nitrogen oxides is reduced. In embodiments, the monohydric alcohol refers to an alcohol with one hydroxyl group in one molecule, and the polyhydric alcohol refers to an alcohol with two or more hydroxyl groups in one molecule.

The monohydric alcohol may have 2 or more carbon atoms in the molecule, for example, 2 to 15, 2 to 13, 2 to 10, or 3 to 10 carbon atoms. In embodiments, the polyhydric alcohol may have 2 or more carbon atoms in the molecule, for example, 2 to 20, 2 to 18, 2 to 15, or 2 to 10 carbon atoms.

The monohydric alcohol may be at least one compound selected from the compounds listed in Group 1.

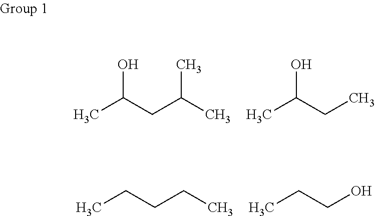

The polyhydric alcohol may be at least one compound selected from the compounds listed in Group 2.

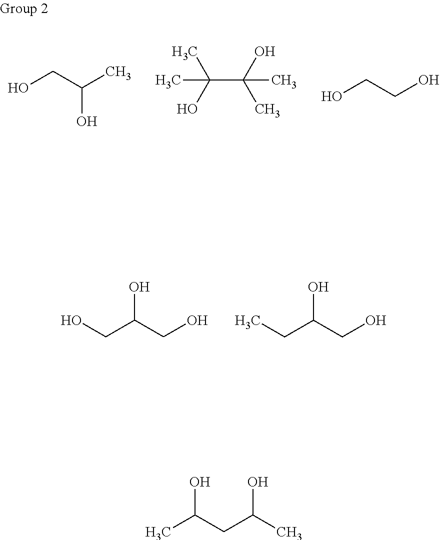

A weight ratio of the compound containing at least one nitro group: the organic acid compound or the alcohol compound may be about 10:90 to about 90:10, for example, about 20:80 to about 90:10, about 20:80 to about 80:20, about 20:80 to about 70:30, about 20:80 to about 60:40, or about 20:80 to about 50:50. If (e.g., when) the weight ratio of the compound containing at least one nitro group: the organic acid compound or alcohol compound satisfies the above ranges, the pattern-forming capability may be improved while the influence of nitrogen oxides is reduced.

The organic acid compound or alcohol compound may be included in an amount of about 0.01 wt % to about 10 wt %, for example, about 0.01 wt % to about 8 wt %, about 0.01 wt % to about 5 wt %, about 0.01 wt % to about 3 wt %, or about 0.05 wt % to about 3 wt % based on 100 wt % of the semiconductor photoresist composition. If (e.g., when) the amount of the organic acid compound or alcohol compound satisfies the above ranges, the profile of the pattern may be further improved.

The organometallic compound may be included in an amount of about 0.5 wt % to about 30 wt %, for example, about 1 wt % to about 30 wt %, about 1 wt % to about 25 wt %, for example, about 1 wt % to about 20 wt %, for example, about 1 wt % to about 15 wt %, for example, about 1 wt % to about 10 wt %, or, for example, about 1 wt % to about 5 wt % based on 100 wt % of the semiconductor photoresist composition. If (e.g., when) the amount of the organometallic compound satisfies the above ranges, the sensitivity of the photoresist may be improved. If (e.g., when) the amount of the organometallic compound satisfies the above ranges, the pattern-forming capability may be improved while the influence of nitrogen oxides is reduced.

The organometallic compound may be an organotin compound containing at least one selected from an organic oxy group and an organic carbonyloxy group.

The organometallic compound may be represented by Chemical Formula 2:

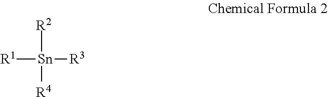

In Chemical Formula 2,
R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R² to R⁴ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy group and/or an aryloxy group (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group or an acyloxy group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido group and/or a dialkylamido group (—NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidate group (—NR^{e}(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{g}C(NR^{h})Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio group and/or an arylthio group (—SR^{j}, wherein R^{j} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from R² to R⁴ is selected from an alkoxy group and an aryloxy group (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group or an acyloxy group (—O(CO)R^{b}, wherein R^{b} is selected from hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

R² to R⁴ may each independently selected from an alkoxy and an aryloxy (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group or an acyloxy group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

In embodiments, because the compound represented by the above Chemical Formula 2 includes —OR^{a} or —OC(═O)R^{b} as a ligand, a pattern formed using a semiconductor photoresist composition including the compound may exhibit excellent limit resolution.

In embodiments, the ligand of —OR^{a} or —OC(═O)R^{b} may determine the solubility of the compound represented by Chemical Formula 2 in a solvent.
R¹ may be a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds (e.g., carbon-carbon double bonds) and/or triple bonds (e.g., carbon-carbon triple bonds), a substituted or unsubstituted C6 to C20 aryl group, a substituted or unsubstituted C4 to C20 heteroaryl group, a carbonyl group, an ethoxy group, a propoxy group, or a combination thereof,
R^{a} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{b} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.
R¹ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof,
R^{a} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof, and
R^{b} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

As another example, the organometallic compound may be represented by Chemical Formula 3 or Chemical Formula 4:

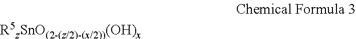

wherein, in Chemical Formula 3,
R⁵ is a C1 to C31 hydrocarbyl group, 0<z≤2, and 0<(z+x)≤4;

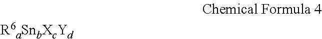

wherein, in Chemical Formula 4,
R⁶ is a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds (e.g., carbon-carbon double bonds) or triple bonds (e.g., carbon-carbon triple bonds), a substituted or unsubstituted C6 to C30 aryl group, a substituted or unsubstituted C4 to C30 heteroaryl group, a carbonyl group, an ethylene oxide group, a propylene oxide group, or a combination thereof,
X is sulfur (S), selenium (Se), or tellurium (Te),
Y is —OR^{m} or —OC(═O)Rⁿ,
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d are each independently an integer of 1 to 20.

The solvent included in the semiconductor photoresist composition according to some example embodiments may be an organic solvent. For example, the solvent may be for example aromatic compounds (e.g., xylene, toluene, and/or the like), alcohols (e.g., 4-methyl-2-pentanol, 4-methyl-2-propanol, 1-butanol, methanol, isopropyl alcohol, and/or 1-propanol), ethers (e.g., anisole, and/or tetrahydrofuran), esters (n-butyl acetate, propylene glycol monomethyl ether acetate, ethyl acetate, and/or ethyl lactate), ketones (e.g., methyl ethyl ketone, and/or 2-heptanone), or a mixture thereof, but is not limited thereto.

The semiconductor resist composition according to some example embodiments may further include a resin in addition to the aforementioned organometallic compound, compound containing at least one nitro group, organic acid compound or alcohol compound, and a solvent.

The resin may be a phenol-based resin including at least one aromatic moiety listed in Group 3.

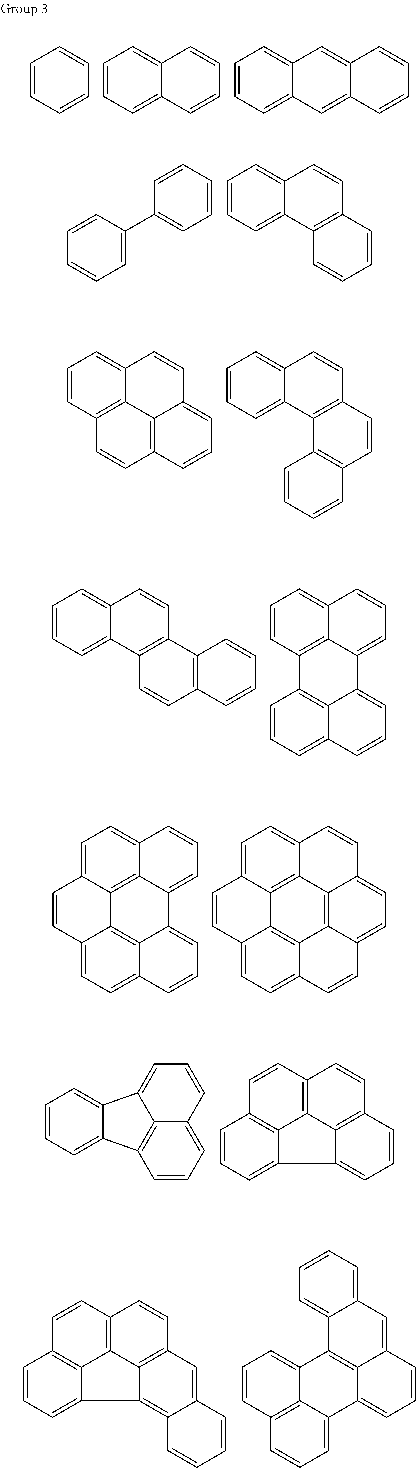

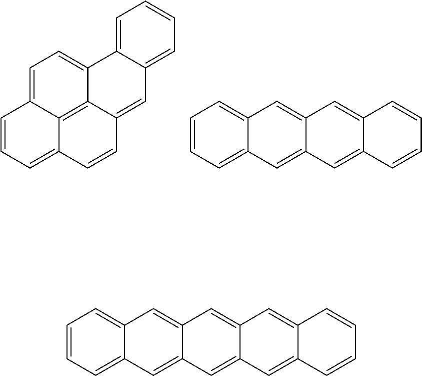

The resin may have a weight average molecular weight of about 500 g/mol to about 20,000 g/mol.

The resin may be included in an amount of about 0.1 wt % to about 50 wt % based on a total amount of the semiconductor photoresist composition. If the resin is included in the above amount range, the semiconductor photoresist composition may have excellent etch resistance and heat resistance.

In embodiments, the semiconductor photoresist composition according to some example embodiments may be composed of the aforementioned organometallic compound, compound containing at least one nitro group, organic acid compound or alcohol compound, a solvent, and a resin.

The semiconductor photoresist composition according to the aforementioned embodiments may further include an additive of a surfactant, a crosslinking agent, a leveling agent, organic acid, a quencher, or a combination thereof as needed.

The surfactant may include for example an alkyl benzene sulfonate salt, an alkyl pyridinium salt, polyethylene glycol, a quaternary ammonium salt, or a combination thereof, but is not limited thereto.

The crosslinking agent may be for example a melamine-based crosslinking agent, a substituted urea-based crosslinking agent, an acrylic crosslinking agent, an epoxy-based crosslinking agent, a polymer-based crosslinking agent, or a combination thereof, but is not limited thereto. It may be a crosslinking agent having at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be used to improve coating flatness during printing and any suitable commercially available leveling agent may be used.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but is not limited thereto.

The quencher may include diphenyl (p-tolyl) amine, methyl diphenyl amine, triphenyl amine, phenylenediamine, naphthylamine, diaminonaphthalene, or a combination thereof, but is not limited thereto.

Each use amount of the additive may be controlled depending on suitable or desired properties.

In embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may include for example a silane compound including a carbon-carbon unsaturated bond such as vinyltrimethoxysilane, vinyl triethoxysilane, vinyl trichlorosilane, vinyl tris(β-methoxyethoxy)silane; and/or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy [3-(phenylamino)propyl]silane, and/or the like, but is not limited thereto.

The semiconductor photoresist composition may be formed into a pattern having a high aspect ratio without a collapse. Accordingly, in order to form a fine pattern having a width of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, or for example, about 5 nm to about 20 nm, the semiconductor photoresist composition may be used for a photoresist process using light in a wavelength in a range from about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to some example embodiments may be used to realize extreme ultraviolet lithography using an EUV light source that emits light having a wavelength of about 13.5 nm.

According to some example embodiments, a method of forming patterns using the aforementioned semiconductor photoresist composition is provided. For example, the manufactured pattern may be a photoresist pattern.

The method of forming patterns according to some example embodiments includes forming an etching-objective layer on a substrate; applying the semiconductor photoresist composition to the etching-objective layer to form a photoresist film; patterning the photoresist film to form a photoresist pattern; and etching the etching-objective layer using the photoresist pattern as an etching mask.

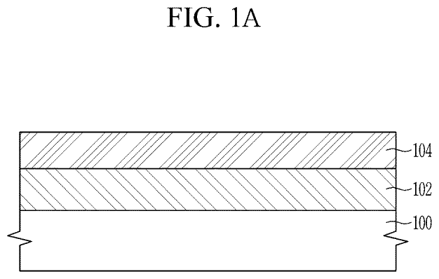

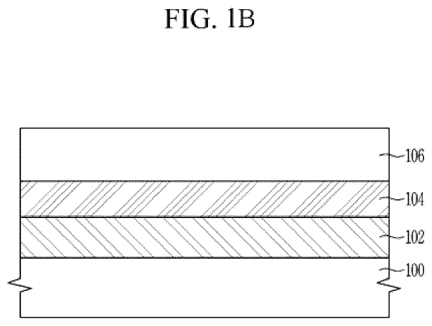

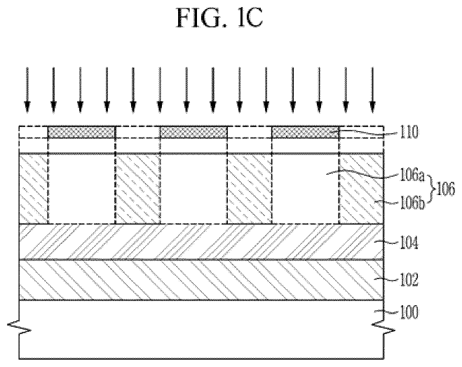

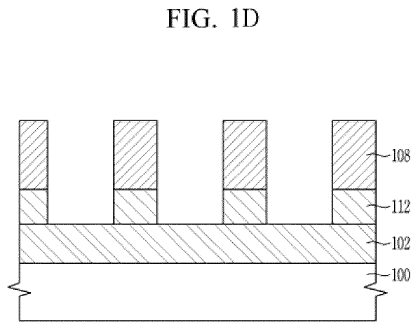

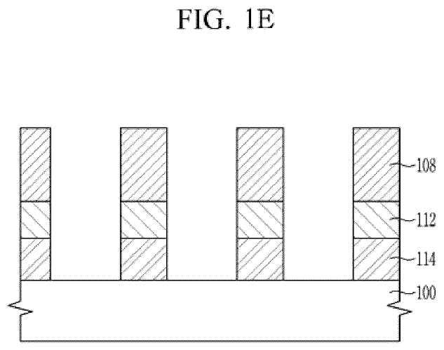

Hereinafter, a method of forming patterns using the aforementioned semiconductor photoresist composition is described referring to FIGS. 1A-1E. FIGS. 1A-1E are cross-sectional views illustrating a method of forming patterns using a semiconductor photoresist composition according to some example embodiments.

Referring to FIG. 1A, an object for etching is prepared. The object for etching may be a thin film 102 formed on a semiconductor substrate 100. Hereinafter, the object for etching is limited to the thin film 102, but the present disclosure is not limited thereto. A surface of the thin film 102 is washed to remove impurities and the like remaining thereon. The thin film 102 may be for example a silicon nitride layer, a polysilicon layer, and/or a silicon oxide layer.

Subsequently, the resist underlayer composition to form a resist underlayer 104 is spin-coated on the surface of the washed thin film 102. However, the embodiments are not limited thereto, and various suitable coating methods, for example a spray coating, a dip coating, a knife edge coating, a printing method, for example an inkjet printing and/or a screen printing, and/or the like may be used.

The coating process of the resist underlayer may be omitted, and hereinafter, a process including a coating of the resist underlayer is described.

Then, the coated composition is dried and baked to form a resist underlayer 104 on the thin film 102. The baking may be performed at about 100° C. to about 500° C., for example, about 100° C. to about 300° C.

The resist underlayer 104 is formed between the substrate 100 and a photoresist film 106 and thus may prevent or reduce non-uniformity and pattern formability of a photoresist line width if (e.g., when) a ray reflected from on the interface between the substrate 100 and the photoresist film 106 and/or a hardmask between layers would otherwise be scattered into an unintended photoresist region.

Referring to FIG. 1B, the photoresist film 106 is formed by coating the semiconductor photoresist composition on the resist underlayer 104. The photoresist film 106 is obtained by coating the aforementioned semiconductor photoresist composition on the thin film 102 formed on the substrate 100 and then, curing it through a heat treatment.

In embodiments, the formation of a pattern by using the semiconductor photoresist composition may include coating the semiconductor resist composition on the substrate 100 having the thin film 102 through spin coating, slit coating, inkjet printing, and/or the like and then, drying it to form the photoresist film 106.

The semiconductor photoresist composition has already been illustrated in detail and will not be illustrated again.

Subsequently, a substrate 100 having the photoresist film 106 is subjected to a first baking process. The first baking process may be performed at about 80° C. to about 120° C.

Referring to FIG. 1C, the photoresist film 106 may be selectively exposed using a patterned mask 110.

For example, the exposure may use an activation radiation including light having a high energy wavelength light such as EUV (extreme ultraviolet; a wavelength of about 13.5 nm), an E-Beam (an electron beam), and/or the like as well as light such as an i-line (a wavelength of about 365 nm), a KrF excimer laser (a wavelength of about 248 nm), an ArF excimer laser (a wavelength of about 193 nm), and/or the like.

In embodiments, light for the exposure according to some example embodiments may be light having a wavelength ranging from about 5 nm to about 150 nm and a high energy wavelength, for example, EUV (extreme ultraviolet; a wavelength of 13.5 nm), an E-Beam (an electron beam), and/or the like.

The exposed region 106b of the photoresist film 106 has a different solubility from the unexposed region 106a of the photoresist film 106 by forming a polymer by a crosslinking reaction such as condensation (e.g., a condensation reaction) between organometallic compounds.

Subsequently, the substrate 100 is subjected to a second baking process. The second baking process may be performed at a temperature of about 90° C. to about 200° C. The exposed region 106b of the photoresist film 106 becomes easily indissoluble regarding a developer due to the second baking process.

In FIG. 1D, the unexposed region 106a of the photoresist film is dissolved and removed using the developer to form a photoresist pattern 108. In embodiments, the unexposed region 106a of the photoresist film is dissolved and removed by using an organic solvent such as 2-heptanone and/or the like to complete the photoresist pattern 108 corresponding to the negative tone image.

As described above, a developer used in a method of forming patterns according to some example embodiments may be an organic solvent. The organic solvent used in the method of forming patterns according to some example embodiments may include for example ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, or a combination thereof.

However, the photoresist pattern according to some example embodiments is not necessarily limited to the negative tone image but may be formed to have a positive tone image. In embodiments, a developer used to form the positive tone image may be a quaternary ammonium hydroxide composition such as tetraethylammonium hydroxide, tetrapropylammonium hydroxide, tetrabutylammonium hydroxide, or a combination thereof.

As described above, exposure to light having a high energy such as EUV (extreme ultraViolet; a wavelength of 13.5 nm), an E-Beam (an electron beam), and/or the like as well as light such as i-line (wavelength of about 365 nm), KrF excimer laser (wavelength of about 248 nm), ArF excimer laser (wavelength of about 193 nm), and/or the like may provide a photoresist pattern 108 having a width of a thickness of about 5 nm to about 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In embodiments, the photoresist pattern 108 may have a pitch of having a half-pitch of less than or equal to about 50 nm, for example less than or equal to about 40 nm, for example less than or equal to about 30 nm, for example less than or equal to about 20 nm, or for example less than or equal to about 15 nm, and a line width roughness of less than or equal to about 10 nm, less than or equal to about 5 nm, less than or equal to about 3 nm, or less than or equal to about 2 nm.

Subsequently, the photoresist pattern 108 is used as an etching mask to etch the resist underlayer 104. Through this etching process, an organic film pattern 112 is formed. The organic film pattern 112 also may have a width corresponding to that of the photoresist pattern 108.

Referring to FIG. 1E, the exposed thin film 102 is etched by applying the photoresist pattern 108 as an etching mask. As a result, the thin film is formed as a thin film pattern 114.

The etching of the thin film 102 may be performed by dry etching using, for example, an etching gas, and the etching gas may be, for example, CHF₃, CF₄, Cl₂, BCl₃, and/or a mixed gas thereof.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width of about 5 nm to about 100 nm which is equal to that of the photoresist pattern 108. For example, the thin film pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, or, for example, a width of less than or equal to about 20 nm, like that of the photoresist pattern 108.

Hereinafter, embodiments the present disclosure will be described in more detail by way of examples of the preparation of the aforementioned semiconductor photoresist composition. However, the present disclosure is technically not restricted by the following examples.

### Synthesis of Organometallic Compounds

### Synthesis Example 1

40.7 g of t-butylSnPh₃ and 300 g of propionic acid were added to a 250 ml two-necked round-bottom flask and heated under reflux for 24 hours. Unreacted propionic acid was removed under reduced pressure to obtain a compound represented by Chemical Formula 5.

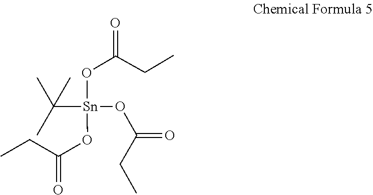 [SMILES: CCC(=O)[O][Sn]([O]C(=O)CC)([O]C(=O)CC)[C](C)(C)C]

### Synthesis Example 2

30 ml of anhydrous pentane was added to 10 g of t-AmylSnCl₃, the temperature was maintained at 0° C., and then 7.4 g of diethylamine and 6.1 g of ethanol were added thereto, and stirred at room temperature for 1 hour. When the reaction was completed, the resultant was filtered, concentrated and vacuum-dried to obtain a compound represented by Chemical Formula 6.

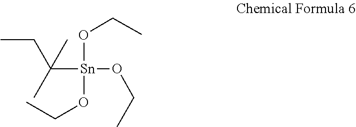

### Synthesis Example 3

10 g of dibutyltin dichloride was dissolved 30 mL of ether, 70 mL of a 1 M sodium hydroxide (NaOH) aqueous solution was added thereto and then, stirred for 1 hour. After the stirring, a solid produced therein was filtered, three times washed with 25 mL of deionized water, and dried at 100° C. under a reduced pressure to obtain an organometallic compound represented by Chemical Formula 7 and having a weight average molecular weight of 1,500 g/mol.

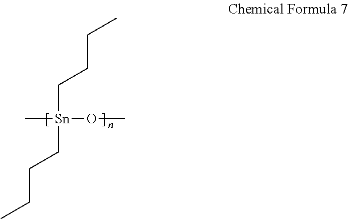

### Preparation of Semiconductor Photoresist Compositions

### Examples 1 to 10

The organometallic compounds represented by Chemical Formulas 5 to 7 according to Synthesis Examples 1 to 3 were respectively dissolved at a concentration of 3 wt % in propylene glycol methyl ether acetate (PGMEA). Subsequently, the organic acid compound (or alcohol compound), and the compound containing at least one nitro group were respectively added and dissolved therein in each amount shown in Table 1 (based on 100 wt % of a semiconductor photoresist composition) and then, filtered with a 0.1 μm PTFE (polytetrafluoroethylene) syringe filter, thereby preparing semiconductor photoresist compositions according to the Examples and Comparative Examples.

TABLE 1

| | | Type of | | Amount of | Amount of |
|---|---|---|---|---|---|
| | | compound | Type of | compound | organic acid |
| | Type of | containing | organic acid | containing | compound |
| | organ- | at | compound | at least one | (or alcohol |
| | ometallic | least one | (or alcohol | nitro group | compound) |
| | compound | nitro group | compound) | (wt %) | (wt %) |
| Example | Chemical | Chemical | 4-methyl-2- | 0.1 | 0.1 |
| 1 | Formula 6 | Formula 1-1 | pentanol | | |
| Example | Chemical | Chemical | 4-methyl-2- | 0.1 | 0.1 |
| 2 | Formula 6 | Formula 1-4 | pentanol | | |
| Example | Chemical | Chemical | n-propyl | 0.1 | 0.1 |
| 3 | Formula 6 | Formula 1-1 | alcohol | | |
| Example | Chemical | Chemical | n-propyl | 0.1 | 0.1 |
| 4 | Formula 6 | Formula 1-4 | alcohol | | |
| Example | Chemical | Chemical | 4-methyl-2- | 0.1 | 0.025 |
| 5 | Formula 6 | Formula 1-1 | pentanol | | |
| Example | Chemical | Chemical | 4-methyl-2- | 0.1 | 0.4 |
| 6 | Formula 6 | Formula 1-1 | pentanol | | |
| Example | Chemical | Chemical | 4-methyl-2- | 0.3 | 0.3 |
| 7 | Formula 6 | Formula 1-1 | pentanol | | |
| Example | Chemical | Chemical | 4-methyl-2- | 0.1 | 0.1 |
| 8 | Formula 7 | Formula 1-1 | pentanol | | |
| Example | Chemical | Chemical | benzoic | 0.1 | 0.1 |
| 9 | Formula 5 | Formula 1-1 | acid | | |
| Example | Chemical | Chemical | malonic | 0.1 | 0.1 |
| 10 | Formula 5 | Formula 1-1 | acid | | |

[Chemical Formula 1-1] 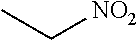
[Chemical Formula 1-4]

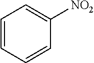

### Comparative Example 1

A semiconductor photoresist composition was prepared in substantially the same manner as in Example 1, except that the compound containing at least one nitro group was not added.

### Comparative Example 2

A semiconductor photoresist composition was prepared in substantially the same manner as in Example 1, except that in Example 1, the alcohol compound in Example 1 was not added.

### Comparative Example 3

A semiconductor photoresist composition was prepared in substantially the same manner as in Example 3, except that in Example 3, the compound containing at least one nitro group was not added.

### Evaluation

The semiconductor photoresist compositions were respectively coated to be 240 Å thick on a silicon wafer and then, processed through PAB (post-application baking), an exposure, PEB (post-exposure baking), and development to form a patterned film.

The semiconductor photoresist compositions according to the examples and the comparative examples were respectively spin-coated on a 200 mm circular silicon wafer deposited with HMDS on the surface at 1,500 rpm for 30 seconds and then, baked (post-apply baked (PAB)) at 110° C. for 60 seconds and allowed to stand at room temperature (23±2° C.) for 30 seconds. Subsequently, EUV light (MET, Lawrence Berkeley National Laboratory Micro Exposure Tool) was projected onto the wafer coated with each of the semiconductor photoresist composition to form a line pattern having a line width of 10 nm (L/S=1/1).

Then, the resist and the substrate were exposed to 170° C. for 60 seconds on a hot plate, baked, and then, developed in a PGMEA solvent. Finally, baking at 150° C. for 60 seconds was performed to complete the process.

The formed pattern was measured with respect to LER (line edge roughness, unit: nm) through SEM (Scanning electron microscopy) to evaluate LER improvement according to the following criteria, and the results are shown in Table 2.

### LER Improvement Evaluation Criteria

o: less than or equal to 2 nm
Δ: greater than 2 nm and less than or equal to 5 nm
x: greater than 5 nm

In addition, each resist was measured with respect to each CD (critical dimension) when there was no NOx (or no detectable NOx) in the air and when there was NOx at a concentration of 0.01 ppm or more by using CD-SEM (critical dimension-scanning electron microscopy) to calculate a CD change (ΔCD (%)), and the results are shown in Table 2. The NOx concentration was measured by using a Sky2000-NOx detector (safe gas). The CD change was calculated according to the following equation.

$$Δ CD = ( CD / {CD}_{0} ) \times 100 \qquad Equation$$

(wherein, in the above chemical formula, CD is a CD value when an NOx concentration was 0.01 ppm or higher, and CD₀ is a CD value when there was no NOx no detectable NOx) in the air.)

TABLE 2

| | LER Improvement | ΔCD (%) |
|---|---|---|
| Example 1 | ∘ | 3 |
| Example 2 | ∘ | 5 |
| Example 3 | ∘ | 12 |
| Example 4 | ∘ | 15 |
| Example 5 | ∘ | 25 |
| Example 6 | ∘ | 8 |
| Example 7 | ∘ | 18 |
| Example 8 | ∘ | 17 |
| Example 9 | ∘ | 10 |
| Example 10 | ∘ | 7 |
| Comparative Example 1 | ∘ | 100 |
| Comparative Example 2 | x | 20 |
| Comparative Example 3 | Δ | 100 |

Referring to Table 2, when used to form a pattern, each of the semiconductor photoresist compositions according to Examples 1 to 10, compared to those of Comparative Examples 1 to 3, exhibited a small CD change according to a concentration change of nitrogen oxide and excellent resistance to influence of the nitrogen oxide. In addition, Examples 1 to 10 were confirmed to exhibit larger LER improvement than Comparative Examples 2 and 3.

For example, Examples 1 and 6 exhibited a smaller CD change according to a concentration change of nitrogen oxide than Example 5. Thus, it can be seen that the weight ratio of the compound containing at least one nitro group: the organic acid compound or the alcohol compound was adjusted to further improve the resistance to influence of nitrogen oxide.

Hereinbefore, certain embodiments of the present disclosure have been described and illustrated, however, it should be apparent to a person having ordinary skill in the art that the present disclosure is not limited to the embodiments as described, and may be suitably, variously modified and transformed without departing from the spirit and scope of the present disclosure. Accordingly, the modified or transformed embodiments as such may not be understood separately from the technical ideas and aspects of the present disclosure, and the modified embodiments are within the scope of the claims, and equivalents thereof, of the present disclosure.

Description of Symbols

| | |
|---|---|
| 100: substrate | 102: thin film |
| 104: resist underlayer | 106: photoresist film |
| 106a: unexposed region | 106b: exposed region |
| 108: photoresist pattern | 112: organic film pattern |
| 110: patterned mask | 114: thin film pattern |

What is claimed is:

1. A semiconductor photoresist composition, comprising:
an organometallic compound;
a compound containing at least one nitro group;
an organic acid compound or an alcohol compound; and
a solvent.

2. The semiconductor photoresist composition as claimed in claim 1, wherein:
the compound containing at least one nitro group is at least one compound selected from a saturated or unsaturated aliphatic compound containing at least one nitro group, and an aromatic ring compound containing at least one nitro group.

3. The semiconductor photoresist composition as claimed in claim 1, wherein:
the compound containing at least one nitro group is a compound represented by Chemical Formula 1: 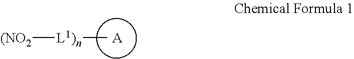
wherein, in Chemical Formula 1,
L¹ is a single bond or a substituted or unsubstituted C1 to C10 alkylene group wherein, —CH₂— in the alkylene is optionally replaced with —O—,
A is at least one selected from substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, and a substituted or unsubstituted C1 to C30 alkylcarbonyl group, and
n is an integer greater than or equal to 1 and less than or equal to the bonding valence of A.

4. The semiconductor photoresist composition as claimed in claim 3, wherein:
in Chemical Formula 1, A is at least one selected from a substituted or unsubstituted C1 to C20 alkyl group, a substituted or unsubstituted C2 to C30 heteroalkyl group, a substituted or unsubstituted C6 to C30 aryl group, and a substituted or unsubstituted C7 to C30 arylalkyl group.

5. The semiconductor photoresist composition as claimed in claim 1, wherein:
the compound containing at least one nitro group is selected from compounds represented by Chemical Formula 1-1 to Chemical Formula 1-12:

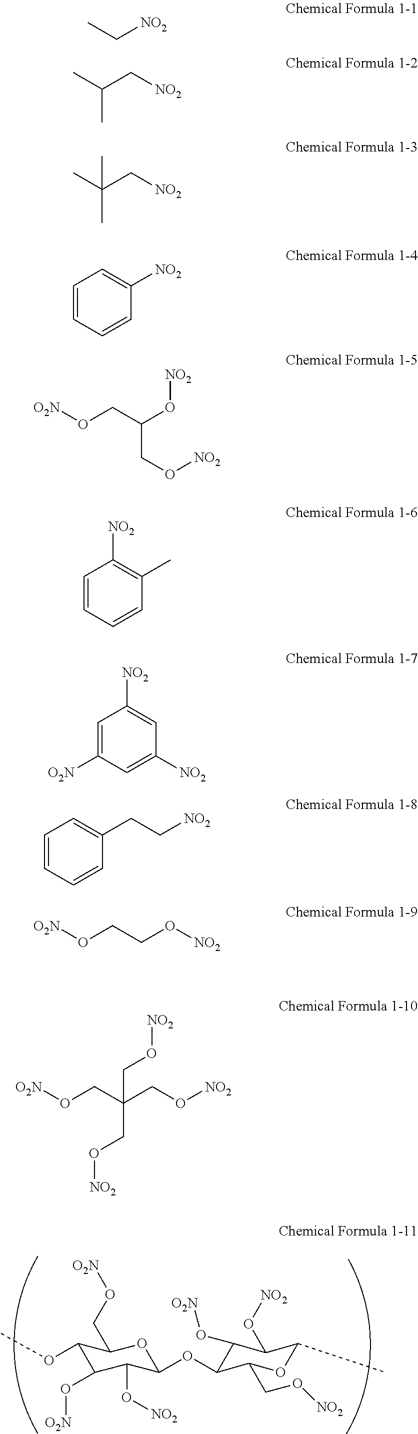

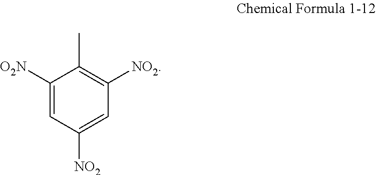 [SMILES: Cc1c([N+](=O)[O-])cc([N+](=O)[O-])cc1[N+](=O)[O-]]

6. The semiconductor photoresist composition as claimed in claim 1, wherein:
the compound containing at least one nitro group is included in an amount of about 0.01 wt % to about 10 wt % based on 100 wt % of the semiconductor photoresist composition.

7. The semiconductor photoresist composition as claimed in claim 1, wherein:
the organic acid compound is a compound containing at least one carboxyl group.

8. The semiconductor photoresist composition as claimed in claim 7, wherein:
the compound containing at least one carboxyl group is at least one compound selected from a saturated or unsaturated aliphatic compound containing at least one carboxyl group, and an aromatic ring compound containing at least one carboxyl group.

9. The semiconductor photoresist composition as claimed in claim 7, wherein:
the compound containing at least one carboxyl group comprises at least one selected from benzoic acid, glycolic acid, malonic acid, succinic acid, 1,2,3,4-butanetetracarboxylic acid, citric acid, tartaric acid, tricarballylic acid, lactic acid, thioglycolic acid, dithiodiglycolic acid, thiodiglycolic acid, phthalic acid, maleic acid, L-aspartic acid, p-toluenesulfonic acid, methanesulfonic acid, and benzenesulfonic acid.

10. The semiconductor photoresist composition as claimed in claim 1, wherein:
the alcohol compound comprises at least one selected from a monohydric alcohol and a polyhydric alcohol.

11. The semiconductor photoresist composition as claimed in claim 1, wherein:
the alcohol compound is a monovalent alcohol.

12. The semiconductor photoresist composition as claimed in claim 1, wherein:
a weight ratio of the compound containing at least one nitro group: the organic acid compound or alcohol compound is about 10:90 to about 90:10.

13. The semiconductor photoresist composition as claimed in claim 1, wherein:
the organometallic compound included in an amount of about 0.5 wt % to about 30 wt % wt % based on 100 wt % of the semiconductor photoresist composition.

14. The semiconductor photoresist composition as claimed in claim 1, wherein:
the semiconductor photoresist composition further comprises an additive comprising a surfactant, a crosslinking agent, a leveling agent, organic acid, a quencher, or a combination thereof.

15. The semiconductor photoresist composition as claimed in claim 1, wherein:
the organometallic compound comprises an organotin compound containing at least one selected from an organic oxy group and an organic carbonyloxy group.

16. The semiconductor photoresist composition as claimed in claim 1, wherein:
the organometallic compound is represented by Chemical Formula 2: 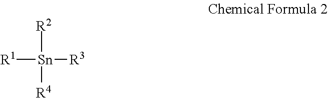
wherein, in Chemical Formula 2,
R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R² to R⁴ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy group and an aryloxy group (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group or an acyloxy group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido group and/or a dialkylamido group (—NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidate group (—NR^{e}(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{g}C(NR^{h})Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio group and an arylthio group (—SR^{j}, wherein R^{j} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and/or a thiocarboxyl group (—S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from R² to R⁴ is selected from an alkoxy group and an aryloxy group (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group or an acyloxy group (—O(CO)R^{b}, wherein R^{b} is selected from hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

17. The semiconductor photoresist composition as claimed in claim 16, wherein:
R² to R⁴ are each independently an alkoxy group and an aryloxy group (—OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a carboxyl group or an acyloxy group (—O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

18. The semiconductor photoresist composition as claimed in claim 17, wherein:
R¹ is a substituted or unsubstituted C1 to C8 alkyl group, a substituted or unsubstituted C3 to C8 cycloalkyl group, a substituted or unsubstituted C2 to C8 aliphatic unsaturated organic group comprising one or more double bond or triple bonds, a substituted or unsubstituted C6 to C20 aryl group, a substituted or unsubstituted C4 to C20 heteroaryl group, a carbonyl group, an ethoxy group, a propoxy group, or a combination thereof,
R^{a} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{b} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

19. The semiconductor photoresist composition as claimed in claim 1, wherein:
the organometallic compound is represented by Chemical Formula 3 or Chemical Formula 4: 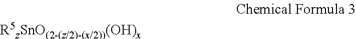
wherein, in Chemical Formula 3,
R⁵ is a C1 to C31 hydrocarbyl group, 0<z≤2, and 0<(z+x)≤4; 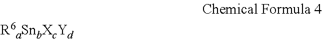
wherein, in Chemical Formula 4,
R⁶ is a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X is sulfur (S), selenium (Se), or tellurium (Te),
Y is —OR^{m} or —OC(═O)Rⁿ,
R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d are each independently an integer of 1 to 20.

20. A method of forming patterns, comprising:
forming an etching-objective layer on a substrate;
applying the semiconductor photoresist composition as claimed in claim 1 to the etching-objective layer to form a photoresist film;
patterning the photoresist film to form a photoresist pattern; and
etching the etching-objective layer using the photoresist pattern as an etching mask.
